(19) United States
(12) Patent Application Publication
(10) Pub. No.: US 2023/0307726 A1
(43) Pub. Date: Sep. 28, 2023

(54) METHODS AND SYSTEM FOR IN OPERANDO BATTERY STATE MONITORING

(71) Applicant: JINAN UNIVERSITY, Guangzhou (CN)

(72) Inventors: Tuan GUO, Guangzhou (CN); Yaohua MAI, Guangzhou (CN); Jiaqiang HUANG, Guangzhou (CN); Xihong LU, Guangzhou (CN); Kaiwei LI, Guangzhou (CN); Hai ZHONG, Guangzhou (CN); Jean-Marie TARASCON, Guangzhou (CN)

(73) Assignee: JINAN UNIVERSITY, Guangzhou (CN)

(21) Appl. No.: 18/022,148

(22) PCT Filed: Aug. 17, 2021
(86) PCT No.: PCT/CN2021/113083

§ 371 Date: Feb. 18, 2023

(30) Foreign Application Priority Data
Aug. 18, 2020 (CN) 202010832469.7

(51) Int. Cl. H01M 10/42; G01R 31/392; H01M 10/48; G01N 21/41; G01N 21/01

(52) U.S. Cl. CPC H01M 10/4285; G01R 31/392; H01M 10/48; G01N 21/41; G01N 21/01; G01N 21/553

(57) ABSTRACT

A method and system for in operando, in situ, and real-time monitoring the state of an electrochemical device, e.g. battery, is provided, which is by means of an optical fiber probe inside the electrochemical device. The method includes: shedding an input light into the optical fiber probe and detecting an output light transmitted therefrom; and determining state of health of the electrochemical device based on the output light. The determination step can be based on a change of the refractive index or of the cladding mode or the surface plasmon resonance, all derived from the output light, in the instant state compared to a prior state. The method can simultaneously detect other parameters including state of charge, temperature, pressure, strain, displacement, vibration, or gas release inside the electrochemical device. With a core mode for correction, the determination of these parameters can also realize a high accuracy.

### CROSS-REFERENCE TO RELATED APPLICATION

The present application claims priority to Chinese Patent Application No. 202010832469.7 filed on Aug. 18, 2020, whose disclosure is hereby incorporated by reference in its entirety.

### TECHNICAL FIELD

This present disclosure relates to the state monitoring technology on electrochemical devices such as batteries, and specifically to an optical fiber based method and system capable of in operando, in situ, and real-time monitoring the state of the electrochemical devices.

### BACKGROUND

With the wide acceptance of electric vehicles and together with the new era of internet of things (IoTs), how to ensure battery reliability and sustainability for lifetime have become a must. To meet such demands, it is becoming crucial to develop advanced diagnostics/prognostics tools that can be embedded into a battery that can work in an in operando, in situ, and/or real-time manner to monitor the evolving chemistry of the battery during the normal charge-discharge cycles that may negatively affect the functionalities (e.g. capacity) of the battery, and/or to monitor the sudden state change of the battery caused by unwanted events such as sudden collisions or with certain internal changes inside the battery (e.g., dendrite growth) that cause the build-up of internal temperatures/pressures/strains/displacements/vibrations, which in turn may impose a high risk for the battery to catch fire or explode.

Currently, considerable efforts have been placed in the quest for new diagnostic techniques beyond the use of current and voltage or the positioning of a few thermal probes in the latest electric vehicles. Generic lithium- and sodium-ion batteries consist of two electrodes immersed in a liquid electrolyte. Nowadays, numerous techniques can in operando track the variations of batteries as a whole, such as monitoring heat flow by isothermal calorimetry, or tracking electrodes cracking by either acoustic or optic means. In contrast, only a few can in operando monitor the electrolyte electrochemical stability that mainly governs the nucleation and growth of solid electrolyte interphase (SEI), which largely influences the lifetime of batteries. Ex situ methods such as infrared spectroscopy, mass spectrometry, and nuclear magnetic resonance provide valuable information about electrolyte decomposition. However, such techniques usually require specific cell designs that take us away from battery operation in the real world. Recent reports show that differential thermal analysis (DTA) is useful to in situ examine the composition of electrolytes but also reports how acoustic transmission mapping can in situ probe the electrolyte depletion. Nevertheless, to be implemented in electric vehicles, these two methods still need to overcome a few challenges, such as the cumbersome DTA apparatus or the liquid coupling agent for acoustics.

All of these are obviously impossible to use for routine monitoring of batteries in normal use and there is a dire need for unobtrusive, inexpensive, and reliable devices that could be deployed (at least in large energy storage systems) to monitor the state of health of batteries in real-time and in operation and to relay diagnostic information to system operators. For this to occur, new techniques must be developed for implanting multi-parameter sensors that are compatible with the harsh electrolyte environments typically found within batteries over the course of their expected operating life.

### SUMMARY

In view of the disadvantages associated with existing battery monitoring approaches, this present disclosure provides an optical fiber-based system and method that can in situ and continuous monitor physical, chemical and electrochemical parameters of batteries (including electrolyte chemistry, ion activities, SEI and dendrite growth), without perturbing battery operation.

In a first aspect, a method that can in operando, in situ, and in a real time manner monitor a state of an electrochemical device is provided, which is by means of an optical fiber probe arranged inside the electrochemical device. The method comprises the steps of: (1) shedding an input light into the optical fiber probe and detecting an output light transmitted from the optical fiber probe; and (2) determining a state of health (SoH) of the electrochemical device based on the output light.

As used herein, and elsewhere throughout the disclosure as well, the term “electrochemical device” is referred to as a device or apparatus which either generates electricity from a chemical reaction (e.g. battery or supercapacitor) or uses electrical energy to cause a chemical reaction (e.g. catalyst). Herein, the battery may include a rechargeable battery and a one-time use battery. Examples of a “battery” may include lithium-ion batteries, lithium metal battery, lead-acid batteries, fuel batteries, sodium-ion batteries, alkali batteries, sodium-sulfur batteries, flow batteries, solid state batteries, hybrid solid-liquid state batteries, metal-air batteries or Zn—MnO₂ batteries, etc. Examples of a “catalyst” may include photo-electrochemical cells, photo-electrolytic cells, photo-catalytic cells, electro-catalytic cells etc. The electrochemical device may be in form of unit cells, modules, packs, or hybrid energy storage devices.

As used herein, the term “state” of the electrochemical device can be regarded as a status of the electrochemical device, and examples thereof can include a state of health (SoH), and/or a state of charge (SoC) of the electrochemical device that are of interest.

Herein the term “state of health (SoH)” is referred to as a status of the electrochemical device regarding whether any component of the electrochemical device is healthy or not. In certain non-limiting situations, such as when the electrochemical device has been used for too long, charge/discharge rate too high, or has undergone certain unfavorable physical or chemical challenges (e.g. leakages, in abnormally high/low temperature, abnormal strikes, etc.), the physiochemical properties of certain components (e.g. electrolyte, electrode, or separator, etc.) inside the electrochemical device may change to an extent such that the health state of the electrochemical device is compromised. In the following, several examples are provided.

In one example, due to a long time use of a battery, the electrolyte of the battery may contain certain solid depositions which may cause the electrolyte to be turbid, thereby affecting the refractory index of the electrolyte. Importantly, such an increase of turbidity in the electrolyte may be correlated with a decrease of capacity of the battery, thus is related to the health state of the battery.

In another example, due to certain situations that have occurred to a lithium battery, lithium dendrites may grow on one or both of the electrodes in the lithium battery, which not only may affect the efficiency, but also may cause a high risk for the lithium battery to catch fire, thereby affecting the health state of the lithium battery. Other rechargeable batteries with a metal anode, such as Li, Na, K, Mg, Zn, Al anode, or graphite electrode can also reportedly grow unfavorable dendrites during operations.

In yet another example, due to certain situations, a change may have occurred on one or a combination of an internal temperature, pressure, strain, displacement, or vibration inside an electrochemical device, which may as well affect the health state of the electrochemical device. For example, a rise in the internal temperature and/or a rise in the internal pressure have been found to be associated with a risk for a lithium battery to catch fire or even to explode.

In yet another example, due to certain situations, a gas (e.g. O₂, H₂, CO, CO₂, C₂H₄, CH₄, HF, etc.) may be produced as a by-product of an unwanted chemical reaction that occurs inside an electrochemical device, which may be an indicator for, and/or may directly affect, the health state of the electrochemical device.

It is noted that any of the above can be detected utilizing the method disclosed herein. It is further noted that these above examples serve as illustration purpose only, and by no means shall be regarded to limit the scope of present disclosure.

Herein the term “state of charge (SoC)” is defined as the rate of the available capacity to its maximum capacity when a battery is completely charged, and describes the remaining percentage of battery capacity.

Herein, the term “optical fiber probe” is referred to as a sensing or detecting apparatus that primarily works utilizing an optical fiber, which can be of the following types such as an optical fiber with a grating, an optical fiber with a cavity, a microfiber, a nanofiber, a tapered fiber, a side-polished fiber, a microstructure fiber and a photonic crystal fiber, etc. Optionally, the optical fiber probe is the type of optical fiber gratings, and the gratings may be one selected from a group consisting of fiber Bragg grating (FBG), tilted fiber Bragg grating (TFBG), long period fiber grating (LPG), chirped fiber gratings, and phase shift gratings.

According to some embodiments, the type of the gratings is tilted fiber Bragg grating (TFBG), and as such may comprise a core and a cladding coating the core. The core may be provided with a tilted grating having an inclination angle less than 90° relative to a longitudinal axis of the core. Herein, the inclination angle of the tilted grating can be in a range of approximately 2°-45°. Further optionally, the optical fiber probe may further comprise a surface plasmon resonance (SPR) layer coating an outer surface of the cladding, which has a composition that is active to SPR. Such a composition may comprise at least one of gold (Au), silver (Ag), platinum (Pt), copper (Cu) or aluminum (Al), a semiconductor material, a metal oxide material, a two-dimensional (2D) material, or an optical metamaterial. Further optionally, the optical fiber probe may further comprise a protective film layer over an outer surface of the SPR layer, which may comprise at least one of diamond, silicon, indium tin oxide (ITO), zinc peroxide (ZnO₂), tin oxide (SnO₂), indium oxide (In□O□), polyethylene (PE) or polypropylene (PP). Further optionally, the optical fiber probe may further comprise a transition film layer sandwiched between the cladding and the SPR layer, which is configured to improve adhesion of the base film layer to the optical fiber, and the transition film layer may comprise at least one of titanium (Ti), molybdenum (Mo), or chromium (Cr).

Typically, the working mechanism of the optical fiber probe is as follows: upon receiving an input light from a light source apparatus, the optical fiber in the optical fiber probe emits an output light, and a signal detection and processing apparatus receives the output light from the optical fiber probe, obtains/extracts signals from the output light, and then processes and analyzes the signals to thereby obtain relevant information or to make a determination of certain other information.

Herein, the expression “inside the electrochemical device” is referred to such that the optical fiber probe can be spatially arranged in any internal place and by any configuration inside the electrochemical device. For example, the optical fiber probe can be arranged in the electrolyte, one or both of the electrodes, the separator, or any of their combinations, or can be at an interface between any of the above components (e.g. at an electrolyte-electrode interface or in a proximity of the electrode).

According to certain embodiments of the method, the determination of the SoH of the electrochemical device relies on the calculation of a refractive index (RI) which is derived from the output light. As such, step (2) of determining a state of health (SoH) of the electrochemical device based on the output light may comprise the following sub-steps:
(i) obtaining a refractive index based on the output light; and
(ii) determining the SoH of the electrochemical device based on a change of the refractive index relative to a prior state of the electrochemical device.

As used herein, the term “a change of the refractive index relative to a prior state of the electrochemical device” is referred to as the difference between the refractive index at an instant/current state and the refractive index at a prior state of the electrochemical device (i.e. RI_{current}−RIₚᵣᵢₒᵣ). Herein, the term “prior state of the electrochemical device” is referred to as a state of the electrochemical device that is prior to the instant state of the electrochemical device. For example, such a prior state may be a pristine state (e.g. after the fabrication, or out-of-factory state) of a battery, or may be a state at one of initial charge-discharge cycles (i.e. cycle number in range of 2-10 cycles after the pristine state), or may just be at a charge-discharge cycle that is earlier than the instant/current moment (i.e. instant charge-discharge cycle).

Optionally, the above sub-step (i) may comprise the sub-steps of: (a) obtaining one of a cladding mode or a surface plasmon resonance (SPR) from the output light; and (b) calculating the refractive index based on the one of the cladding mode or the SPR.

According to certain embodiments, the optical fiber probe may comprise a core, a cladding, and an SPR layer coating the cladding, and as such, the output light may comprise a SPR, based on which the calculation of the refractive index may be performed. According to some other embodiments, the optical fiber probe may comprise a core and a cladding, and comprises no SPR layer, and as such, the output light may comprise a cladding mode, based on which the calculation of the refractive index may be performed.

In any of the above embodiments, the output light comprises a core mode, and optionally in the above sub-step (b), the refractive index can be calculated further with correction of the core mode.

According to certain embodiments of the method, the above sub-step (ii) further comprises: determining that the electrochemical device is unhealthy if the refractive index is changed by at least a first threshold relative to the prior state of the electrochemical device. Herein the first threshold may be a percentage that is more than 0%, which can be 1%, 2%, 5%, 10%, or 20% depending on the sensitivity level.

According to some other embodiments of the method, the determination of the SoH of the electrochemical device may directly rely on the output light without the conversion of the output light into the calculation of the refractive index.

According to certain embodiments of the method, the above step (2) comprises the sub-steps of: (i) obtaining one of a cladding mode or a surface plasmon resonance (SPR) from the output light; and (ii) determining the SoH of the electrochemical device based on a wavelength shift or an amplitude change of the one of the cladding mode or the SPR relative to a prior state of the electrochemical device.

Herein optionally, the above sub-step (ii) may comprise the sub-steps of: (a) taking a derivative of the one of the cladding mode or the SPR with respect to one selected from a group consisting of time, voltage, current, resistance and capacity; and (b) determining the SoH of the electrochemical device based on the derivative.

According to some embodiments, the sub-step (ii) may comprise: (a) determining that the electrochemical device is unhealthy if an amplitude or wavelength of the one of the cladding mode or the SPR is changed by at least a second threshold relative to the prior state of the electrochemical device. Herein the second threshold may be a percentage that is more than 0%, which can be 1%, 2%, 5%, 10%, or 20% depending on the sensitivity level.

Herein, according to certain embodiments, at least one portion of a detection surface of the optical fiber probe is in contact with an electrolyte of the electrochemical device, and as such the determining that the electrochemical device is unhealthy in sub-step (a) comprises: determining that the electrolyte is unhealthy. As used herein, the term “unhealthy” may refer to an abnormal situation of the electrolyte which may negatively affect the function/operation of the electrochemical device. Example may include that the electrolyte is aged, degraded, denatured, etc.

According to certain embodiments of the method, step (2) may comprise the sub-steps of: (i) obtaining one of a cladding mode or a surface plasmon resonance (SPR) from the output light; and (ii) determining the electrochemical device is unhealthy if at least one secondary peak is present in the one of the cladding mode or the SPR. As used herein, the term “secondary peak” is referred to as any peak other than the expected primary peak in the cladding mode or the SPR, with specific examples and more description provided below.

According to certain embodiments, the optical fiber probe is inside or in a proximity of an electrode of the electrochemical device, and as such, the determining that the electrochemical device is unhealthy in sub-step (ii) comprises: determining that the electrode is unhealthy. As used herein, the term “unhealthy” may refer to an abnormal situation of the electrode which may negatively affect the function/operation of the electrochemical device. Examples may include that the electrode has dendrite grown thereon, or is aged, broken, etc.

In any one of preceding embodiments, the method may further comprise, after step (1): a step of determining a state of charge (SoC) of the electrochemical device based on the output light.

According to certain embodiments, the above step of determining a state of charge (SoC) of the electrochemical device based on the output light comprises the sub-steps of: (i) obtaining one of a cladding mode or an SPR from the output light; and (ii) determining the SoC of the electrochemical device based on the one of the cladding mode or the SPR.

Herein, according to some embodiments, the above sub-step (ii) may comprise the sub-steps of: (a) calculating a refractive index based on the one of the cladding mode or the SPR; and (b) determining the SoC based the refractive index. According to some other embodiments, the above sub-step (ii) may comprise: (a) taking a derivative of the one of the cladding mode or the SPR with respect to one selected from a group consisting of time, voltage, current, resistance and capacity; and (b) determining the SoC based the derivative.

In any of the above embodiments where SoC is determined, in sub-step (i), a core mode may be optionally further obtained from the output light, and in sub-step (ii), the SoC is determined with further correction of the core mode.

In any one of the above embodiments, the method may further comprise, after step (1): a step of determining at least one of a temperature, a pressure, a strain, a displacement, a vibration, or a gas release inside the electrochemical device based on the output light. Herein, according to certain embodiments, a gas is determined, which can be one or more of O₂, H₂, CO, CO₂, C₂H₄, CH₄, and HF.

Herein, the determination of temperature can be based a wavelength shift of the core mode, the cladding mode or the SPR; the determination of pressure/strain/displacement/vibration can be based on differential wavelength shift or an amplitude change between core mode and the one of the cladding mode or the SPR; the determination of the gas release can be based on differential wavelength shift or an amplitude change between the core mode and the one of the cladding mode or the SPR; and the determination of the type of gas can be based on the specific spectral absorption or by specific materials functionalization.

In a second aspect, a system that can implement any of the above mentioned embodiments of the method to thereby realize in operando, in situ, and real time monitoring of a state of an electrochemical device is further provided.

The system comprises an optical fiber probe, a light source apparatus, and a signal detection and processing apparatus. The optical fiber probe is arranged inside the electrochemical device. The light source apparatus is optically coupled to a first end (i.e. light-in end) of the optical fiber probe, and works to provide an input light into the optical fiber probe. The signal detection and processing apparatus is optically coupled to the optical fiber probe, which works by receiving an output light from the optical fiber probe, obtaining signals from the output light; and processing the signals such that step (2) of determining a state of health (SoH) of the electrochemical device based on the output light in any one of the embodiments of the method as described above is implemented.

Herein the detailed description for the electrochemical device, the optical fiber probe can reference to the above description provided for the method, and will be skipped herein for conciseness.

According to different embodiments, the optical fiber probe may work in a transmission mode or in a reflection mode.

In the transmission mode, the light source apparatus and the signal detection and processing apparatus are substantially arranged at two opposing side of the optical fiber probe, with the light source apparatus optically coupled to the first end (i.e. light-in end) of the optical fiber probe, and with the signal detection and processing apparatus optically coupled to a second end (i.e. light-out end) of the optical fiber probe.

In the reflection mode, the light source apparatus and the signal detection and processing apparatus are substantially arranged at a same side of the optical fiber probe, and are optically coupled to a same end (i.e. the first end) of the optical fiber probe. Herein, the first end of the optical fiber probe is substantially both a light-in end and a light-out end. In this mode, a mirror is typically arranged at a second end (i.e. the end opposing the first end), whose reflective surface is arranged to face inside the optical fiber probe. The mirror is configured to reflect optical lights (i.e. generated and/or transmitted) in the optical fiber probe back towards the first end (i.e. light-in end) of the optical fiber probe. Further in this mode, the system may further include an optical fiber circulator, which is optically arranged between the light source apparatus and the optical fiber probe along an input optical pathway and between the optical fiber probe and the signal detection and processing apparatus along an output optical pathway. The optical fiber circulator is configured to separate the input optical pathway and the output optical pathway to thereby allow the signal detection and processing apparatus to obtain the signals of the cladding modes or SPR from the optical fiber probe without being influenced by the input light.

Herein, the light source apparatus may comprise a light source, an optional polarizer, and an optional polarization controller, which are sequentially arranged along an optical pathway into the optical fiber probe. According to some embodiments, the light source comprises a broadband source (BBS), and the signal detection and processing apparatus comprises an optical spectrum analyzer (OSA). According to some other embodiments, the light source comprises a tunable laser source (TLS), and the signal detection and processing apparatus comprises an optical detector and an analog-to-digital converter. The optical detector is configured to detect, and to convert into analog electrical signals, the signals from the sensing apparatus; and the analog-to-digital converter is configured to convert the analog electrical signals into digital electrical signals.

Herein, depending on different embodiments, the optical fiber probe may have a single-point or a multiple-point configuration. In one embodiment, the optical fiber probe may have a single-point configuration, comprising one single functional module (it can be regarded as one single optical fiber sensor) that is specifically for certain purpose such as for the detection of refractive index change of the electrolyte in a battery. Additionally, due to the fact that an optical fiber can offer multiplex sensing ability, more than one functional modules (i.e. each can be regarded as one optical fiber sensor that serves a different purpose) may work in one single optical fiber probe (i.e. via a series way), which together share a same light source apparatus and a same signal detection and processing apparatus that are operably connected to the one single optical fiber probe. Yet according to certain embodiments, a plurality of functional modules (i.e. optical fiber sensors) may work in multiple-fibers (i.e. via a parallel way), which together may also share a same light source apparatus and a same signal detection and processing apparatus that are operably connected to the multiple optical fiber probes.

### BRIEF DESCRIPTION OF THE DRAWINGS

FIGS. 1A and 1B respectively illustrate a perspective view of two embodiments of an optical fiber probe that is utilized for monitoring the battery state;

FIG. 2 illustrates a block diagram of an electrochemical device state monitoring system;

FIGS. 3A and 3B illustrate the evolution of cladding mode amplitude of the output optical signals in response to the electrolyte concentration;

FIGS. 4A and 4B illustrate the evolution of wavelengths of the output optical signals in response to the electrolyte concentration;

FIGS. 5A and 5B illustrate the evolution of wavelengths of the output optical signals in response to the temperature;

FIG. 6 shows the evolution of spectra of the output optical signals in response to the SoH of the electrochemical device;

FIGS. 7A-7C show the capacity retention together with the measured changes in refractive index and turbidity of electrolyte as a function of cycle number;

FIGS. 8A-8C show one kind of relationship between the dendrite growth state of the electrode and output light during charging and discharging;

FIGS. 9A and 9B show another relationship between the dendrite growth state of the electrode and output light during charging and discharging;

FIG. 10A shows the correspondence between the electrochemical signal, optical signal and the change rate of optical signal of electrolyte-electrode interactions near the electrode surface; and

FIG. 10B shows the relationship curve between the optical signal d(dB)/dt and the potential during charging and discharging.

### DETAILED DESCRIPTION OF THE INVENTION

In the following, exemplary embodiments are provided below, which are described in sufficient detail to enable those of ordinary skill in the art to embody and implement the methods and systems described above. It is to be understood that these embodiments can be provided in many varying forms and should not be construed as a limitation to the scope covered by the present disclosure.

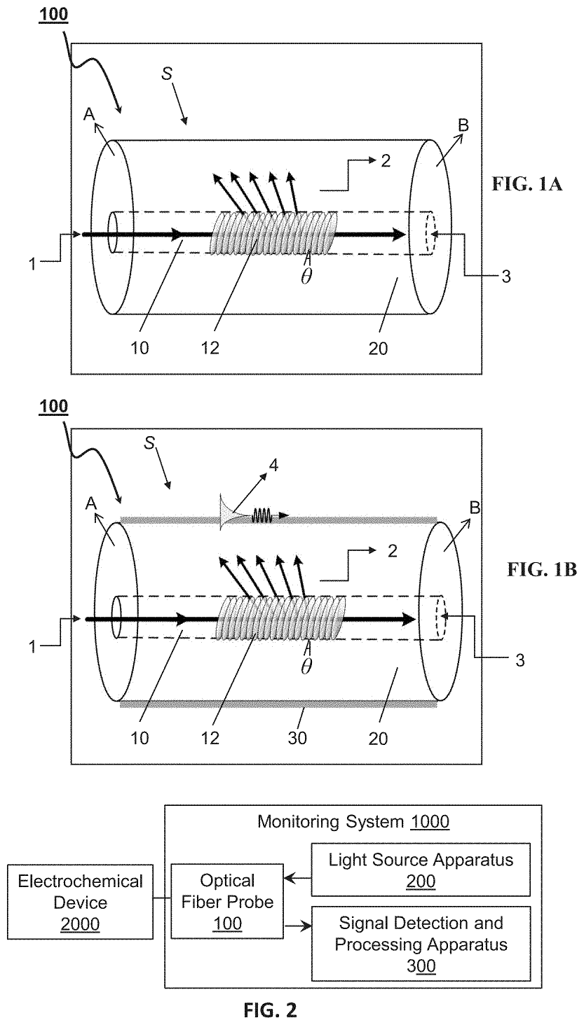

In a first aspect, an optical fiber probe that is utilized in the above mentioned method for in operando, in situ, and in a real time manner monitoring a state of an electrochemical device is provided. The optical fiber probe is arranged inside the electrochemical device (e.g. battery). FIGS. 1A and 1B respectively illustrate a perspective view of two embodiments of the optical fiber probe.

As shown in FIG. 1A, this embodiment of the optical fiber probe 100 is substantially an optical fiber with tilted fiber Bragg grating (i.e. TFBG), and comprises a core 10 and a cladding 20 coating the core 10, which are arranged coaxially to together form an optical fiber. The core 10 of the optical fiber probe 100 is provided with a tilted grating 12, i.e. a grating having an internal tilt angle θ (defined as an angle of each plane of the grating relative to a plane that is substantially perpendicular to the axis of the core 10). The cladding 20 of the optical fiber probe 100 is in contact with one component S, such as the electrolyte or the electrode, etc., of the electrochemical device, so as to determine the various parameters of the electrochemical device including SoH, and optionally the SoC, the internal temperature, the internal pressure, the internal strain, the internal displacement, and/or the internal vibration. Upon an input light 1 entering from a first side surface (i.e. light-in end surface) A into the optical fiber probe 100 and transmitting along the core 10, the tilted grating 12 can reflect and/or refract the input light into the cladding 20 of the optical fiber probe 100 (the light such reflected or refracted is shown as 2 in FIG. 1A). The output light thus emitted out from a second side surface (i.e. light-out end surface) B may comprise a core mode 3 and cladding mode 2. The cladding mode 2 may contain information that can be used for the determination of the various parameters as mentioned above.

FIG. 1B illustrates another embodiment of the optical fiber probe 100, which is configurationally similar to the embodiment shown in FIG. 1A, but differs by additionally comprising an SPR layer 30 coating an outside of the cladding 20. The SPR layer 30 may have a thickness of approximately 20-70 nm and preferably of approximately 30-50 nm, and may comprise a composition that is active to surface plasmon resonance (SPR), and thus upon an input light 1 entering from the light-in end surface A into the optical fiber probe 100 and transmitting along the core 10, the output light may include, in addition to the core mode 3 and the cladding mode 2, a surface plasmon wave (i.e. SPR) 4. The SPR 4 may contain information that can be used for the determination of the various parameters of the electrochemical device as mentioned above. In either of the two embodiments mentioned above, the input light 1 can be generated by a light source apparatus that is optically connected to the light-in end surface A of the optical fiber probe, and the output light can be captured by a signal detection and processing apparatus that is optically connected to the light-out end surface B of the optical fiber probe, which may comprise an optical spectrometer. Optionally for each of the two embodiments of the optical fiber probe 100 shown in FIGS. 1A and 1B, a mirror with a reflecting surface facing the inside of the optical fiber probe 100 may be arranged at the second end surface B of the optical fiber probe 100, which can reflect the output light back to thereby emit out of the first end surface A (which is thereby both a light-in end surface and a light-out end surface) of the optical fiber probe 100.

In addition to the embodiment of the optical fiber probe illustrated in FIG. 1B, optionally, a protective film layer may be arranged over an outer surface of the SPR layer, and a transition film layer may be sandwiched between the cladding and the SPR layer. More details for the SPR layer, the protective film layer, and/or the transition layer can be found above and will be skipped herein.

It is noted that there can be a variety of embodiments for the optical fiber probe in addition to the two embodiments illustrated in FIGS. 1A and 1B. For example, the optical fiber probe can be fiber gratings, a micro-nano fiber, a micro-structure fiber, a fiber micro-cavity, and the like. The material of the optical fiber can be quartz, polymer, micro-structured optical fiber and so on. Fiber gratings include, but are not limited to, uniform gratings, chirped fiber gratings, phase-shifted gratings, tilted fiber Bragg gratings (TFBG), fiber Bragg gratings (FBG), long-period fiber gratings (LPG), and for gratings prepared on optical fibers based on different doped materials. For example, a Bragg grating prepared based on doped polymethyl methacrylate (PMMA) fiber. The optical fiber probe can also be a structural improvement of the above-mentioned various gratings, such as micro-nano fiber gratings. In addition, the number of optical fiber probes involved in the present application is not limited. For example, it may be one or more. For another example, part of them may be tilted fiber gratings, and part of them may be fiber Bragg gratings. When there are multiple optical fiber probes, the connection mode of each optical fiber probe is also not limited. For example, they may be connected in series or in parallel. For the sake of simple description, the present application takes one TFBG as an example for description of the fiber probe.

In a second aspect, a monitoring system comprising the above mentioned optical fiber probe that is utilized for the in operando, in situ, and real-time monitoring of a state of an electrochemical device is further provided. As shown in FIG. 2, the system 1000 comprises, in addition to the optical fiber probe 100, a light source apparatus 200, and a signal detection and processing apparatus 300. The light source apparatus 200 and the signal detection and processing apparatus 300 are respectively configured to be optically connected to the optical fiber probe 100 (via a light-in end surface and a light-out end surface, respectively, which are not shown in FIG. 2). The optical fiber probe 100 of the monitoring system 1000 is operably coupled with the electrochemical device 2000 by specifically being arranged there inside. Regarding the different types and configurations for the light source apparatus 200 and the signal detection and processing apparatus 300, details can reference to the description set forth above.

In the monitoring system 1000, the light source apparatus 200 works by providing an input light into the optical fiber probe 100, and the signal detection and processing apparatus 300 works by receiving an output light from the optical fiber probe, obtaining signals from the output light, and processing the signals such that the various parameters of the electrochemical device 2000, including SoH, and optionally the SoC, the internal temperature, the internal pressure, the internal strain, the internal displacement, vibration, and/or gas, can be derived therefrom.

The optical fiber probe 100 may work on two different working modes. In the transmission mode, the light source apparatus 200 and the signal detection and processing apparatus 300 are respectively arranged at two opposing ends of the optical fiber probe 100 (i.e. the light-in end surface and the light-out end surface are different). In the reflection mode, the light source apparatus 200 and the signal detection and processing apparatus 300 are respectively arranged at a same side of the optical fiber probe 100, i.e. both are connected to a same first end surface (i.e. the light-out end surface is substantially also the light-in end surface), and in this mode, a mirror is arranged at a second end surface opposing to the first end surface to reflect the output light back to the first end surface. Further in this reflection mode, the monitoring system 1000 may further include an optical fiber circulator (not shown), which can separate the input optical pathway and the output optical pathway.

The following are noted. The electrochemical device may be a battery, which comprises an electrolyte and at least two types of electrodes, that is, at least a positive electrode and a negative electrode. The optical fiber probe can be partially immersed in the electrochemical device, or fully immersed in the electrochemical device. The position of the optical fiber probe in the electrochemical device is not limited. For example, it can be in the electrolyte or adjacent to the electrode. The “adjacent” referred to in the present application may mean that the optical fiber probe is in close contact with the electrode, or may mean that the optical fiber probe and the electrode are slightly apart, which is not limited in the embodiment of the present application.

In a third aspect, a method that substantially utilizes the above monitoring system 1000 for the in operando, in situ, and real-time monitoring of a state of an electrochemical device 2000 is further provided.

The method comprises the steps of: (1) shedding an input light into the optical fiber probe and detecting an output light transmitted from the optical fiber probe; and (2) determining a state of health (SoH) of the electrochemical device based on the output light.

Optionally, according to different embodiments of the method, after step (1), other type of information such as a state of charge (SoC), an internal temperature/pressure/strain/displacement/vibration/gas may also be determined by analyzing the output light.

Depending on the different signal processing approaches, step (2) may be realized by converting the output light into the calculation of a refractive index, and the determination of the various parameters, or alternatively by directly analyzing the cladding mode or SPR in the output light. A change of the refractive index or a change of the cladding mode or SPR (e.g. an amplitude change or a wavelength shift) in the instant state of the electrochemical device relative to a prior state of the electrochemical device may be examined, with the detection of such a change more than a certain pre-set threshold (e.g. 1%, 2%, 5%, 10%, 20%, or 50%, etc.) being regarded as an unhealthy state for the electrochemical device, or more specifically for the electrolyte or electrode if the actual arrangement of the optical fiber probe inside the electrochemical device is known.

In the following, three different examples (Examples 1, 2 and 3) are provided below for more detailed description, yet it is noted that these examples are for illustration purpose only and shall not be interpreted to limit the scope of the present disclosure.

This application uses TFBG and a lithium-ion battery as an example for description, and the angle and length of the TFBG are not limited in the embodiment of this application. In the following description, the angle of the inclined fiber grating used is θ and the length is L. The lithium-ion battery used includes two electrodes, namely a positive electrode and a negative electrode. According to another embodiment, the refractive index of the electrolyte can be derived from the amplitude of the cladding modes or SPR for detecting the SoH of the electrochemical devices. Namely, the amplitude of the cladding mode changes with the refractive index, indicating the degradation of the electrolyte and thus the decay in SoH of electrochemical devices. In other words, when the electrochemical devices degrade, the possible deterioration in electrolyte will induce its refractive index change and finally lead to the amplitude change of the output optical signals. Preferably, the electrochemical devices are determined to be unhealthy if the refractive index, measured by the amplitude method, is changed by at least 1%.

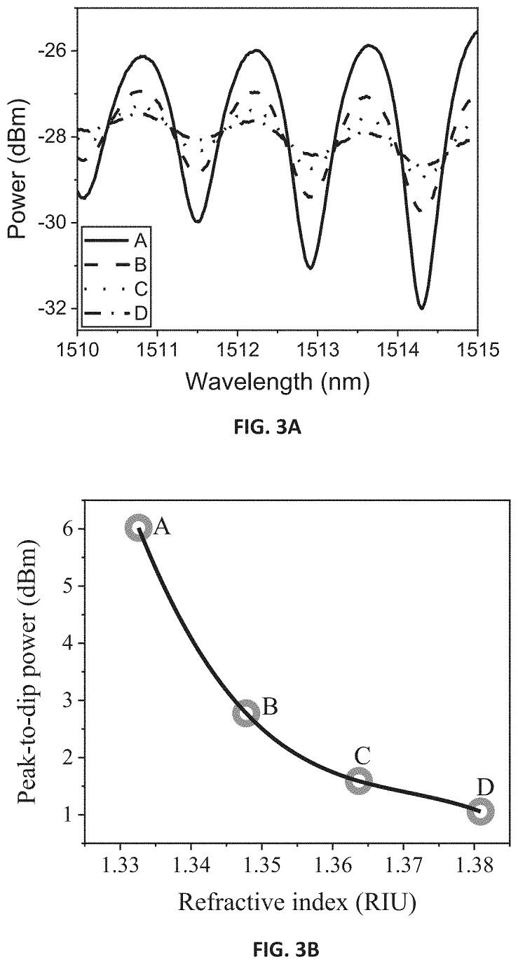

Specially, FIG. 3A provides an example of the evolution of cladding mode amplitude of the output optical signals in response to the electrolyte concentration. As shown in FIG. 3A, the abscissa and the ordinate represent the spectral range and the power (amplitude) of the output light, respectively. As an example, spectra within 1510 to 1515 nm and −32 to −26 dBm are shown in FIG. 3A. The solid, dash, dot, and dot dash lines indicates the output spectra when the probe immersed in the electrolyte at concentrations of A, B, C, and D, respectively, where A<B<C<D. FIG. 3A shows the different spectra with varied electrolyte concentration, that is, the amplitude of the cladding mode decreases with the concentration of electrolyte. Among the three cladding modes shown in FIG. 3A, at least one mode should be selected for the analysis. FIG. 3B thus provides the correlation between the refractive index of the electrolyte and the amplitude of one cladding mode. Notably, the refractive index of the electrolyte can be derived from the concentration according to the references, which is not discussed here. The abscissa and the ordinate of FIG. 3B represent the refractive index range (from 1.33 to 1.38) and the peak-to-dip power (from 1 to 6 dBm) of the output light, respectively. Note that the other amplitude analysis methods are feasible and not limited to the peak-to-dip power, for example, the power of a single peak or the upper and lower envelopes. FIG. 3B shows that the refractive index increases from A to D with the decrease of the peak-to-dip power.

According to another embodiment, the refractive index of the electrolyte can be derived from the wavelength of the output light for detecting the SoH of the electrochemical devices. Namely, the wavelength either increases or decreases with the refractive index. Note that the shifting direction of the wavelength depends on the type of optical probe and will not be discussed in detail here. When the electrochemical device becomes unhealthy and the refractive index of electrolyte changes, the real-time monitored wavelength will drift. Preferably, the electrochemical devices are determined to be unhealthy if the refractive index, measured by the amplitude method, is changed by at least 1%.

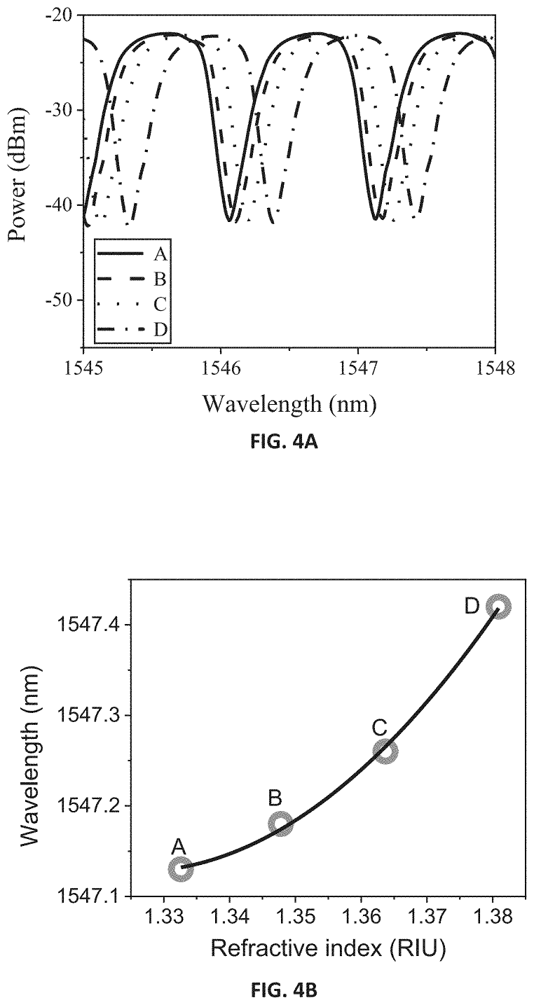

Specially, FIG. 4A provides an example of the evolution of wavelengths of the output optical signals in response to the electrolyte concentration. As shown in FIG. 4A, the abscissa and the ordinate represent the spectral range (from 1545 to 1548 nm as an example) and the power (amplitude, from −50 to −20 dBm as an example) of the output light, respectively. The solid, dash, dot, and dot dash lines indicates the output spectra when the probe immersed in the electrolyte at concentrations of A, B, C, and D, respectively, where A<B<C<D. FIG. 4A shows the different spectra with varied electrolyte concentration, that is, the wavelength of the cladding mode increases with the concentration of electrolyte. Among the three cladding modes shown in FIG. 3A, at least one mode should be selected for the analysis. FIG. 4B thus provides the correlation between the refractive index of the electrolyte and the wavelength of one cladding mode. The abscissa and the ordinate of FIG. 4B represent the refractive index range (from 1.33 to 1.38) and the wavelength (from 1547.10 to 1547.45 nm) of the output light, respectively. FIG. 4B shows that the refractive index increases from A to D with the increase of the wavelength.

According to another embodiment, the temperature of the device can be derived from the wavelength of the output light. Namely, the wavelength changes with the temperature.

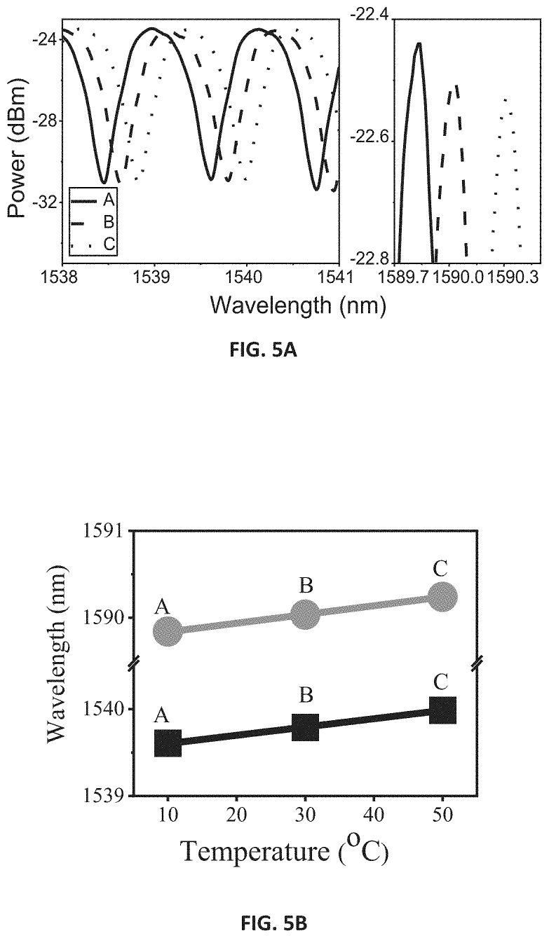

Specially, FIG. 5A provides an example of the evolution of wavelengths of the output optical signals in response to the temperature. As shown in FIG. 5A, the abscissa and the ordinate represent the spectral range (from 1538 to 1541 nm and from 1589.7 to 1590.5 nm for cladding and core modes, respectively, as an example) and the power (amplitude, from −35 to −23 dBm and from −22.8 to −22.4 nm for cladding and core modes, respectively, as an example) of the output light, respectively. The solid, dash, and dot lines indicates the output spectra when the probe at temperatures of A, B, and C, respectively, where A<B<C. FIG. 5A shows the different spectra with varied temperature, that is, the wavelength of the cladding and core modes increases with the concentration of electrolyte. Among the three cladding modes and one core mode shown in FIG. 5A, at least one mode should be selected for the analysis. FIG. 5B thus provides the correlation between the temperature and the wavelength of one cladding and one core modes. The abscissa and the ordinate of FIG. 5B represent the temperature range (from 5 to 65° C.) and the wavelength (from 1539 to 1540.5 nm and from 1589.5 to 1591 nm) of the output light, respectively. The computation of refractive index and temperature can be conducted according to the calibration curves as shown in FIG. 3B, FIG. 4B, and FIG. 5B.

The following are specific applications of the above methods in detecting SoH of the battery.

In Example 1, the turbidity of the electrolyte can be derived from the amplitude of the guided cladding modes for detecting the SoH of the electrochemical devices. Namely, the amplitude of the guided cladding mode decreases with the turbidity of electrolyte, indicating the degradation of the electrolyte and thus the decay in SoH of electrochemical devices. In other words, when the electrochemical devices degrade, the possible deterioration in electrolyte will induce the change in turbidity and finally lead to the amplitude change of the output light. Preferably, the electrochemical devices are determined to be unhealthy if the turbidity metric, namely, the amplitude of the guided cladding modes, is changed by at least 1%.

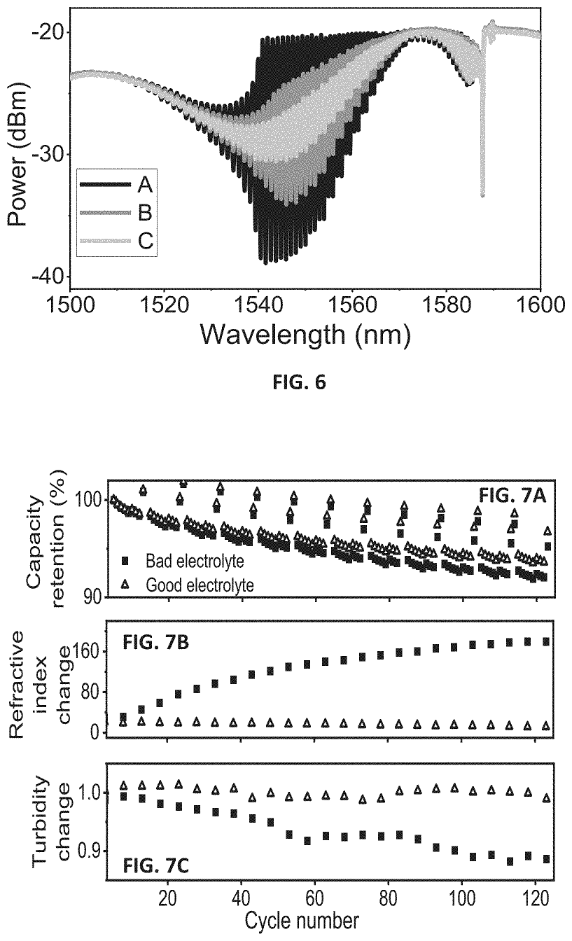

Specially, FIG. 6 provides an example of the evolution of spectra of the output optical signals in response to the SoH of the electrochemical device. As shown in FIG. 6, the abscissa and the ordinate represent the spectral range (from 1500 to 1600 nm) and the power (amplitude, from −41 to −18 dBm) of the output light, respectively. The black, gay, and light gray lines indicate the output spectra when the electrochemical device at SoH of A, B, and C, respectively, where A>B>C. FIG. 6 shows the different spectra with varied SoH, that is, the amplitude of the guided cladding mode decreases with the decrease of SoH of electrochemical devices.

According to another embodiment, FIGS. 7A-7C show the capacity retention together with the measured changes in refractive index and turbidity of electrolyte as a function of cycle number. As shown, the abscissa represents the cycle number (from 3 to 125), while the ordinates in the top (FIG. 7A), middle (FIG. 7B), and bottom (FIG. 7C) panels represent the capacity retention (from 90 to 102%), the refractive index change (from −10 to 220 MU), and the turbidity change (from 0.85 to 1.05). The black squares and light gray diamonds indicate the data when the electrochemical device adopting a bad and a good electrolyte, respectively. FIG. 6 shows that the capacity retention of the electrochemical device with a bad electrolyte decreases faster than the one with a good electrolyte, and the fast degraded electrochemical device also presents more changes in refractive index and turbidity. These results support that the monitoring of refractive index and turbidity can be used to monitor the SoH of electrochemical devices.

In Example 2, the lithium dendrites can be derived from the power of the cut-off mode for detecting the SoH of the electrochemical devices.

Specially, the electrochemical device includes two symmetrical Li metal electrodes in liquid electrolyte. Symmetrical cells were assembled by two identical lithium metal electrodes with a distance in the quartz electrolytic cell. And the electrolyte includes 4 mol L⁻¹ Lithium Hexafluorophosphate in ethylene carbonate (EC), ethyl methyl carbonate (EMC), and dimethyl carbonate (DMC) (1:1:1, v/v/v, respectively) was prepared (denoted as 4 mol L⁻¹ LiPF₆ EC:EMC:DMC). An optical fiber probe tightly attached to one of the electrode for surface-localized and fast changing ionic concentrations near the electrode surface.

In a possible implementation manner, the growth of dendrites can be qualitatively analyzed by the wavelength of the output light or the power change of the cladding mode. More specifically, it can be judged whether there is dendrite growth by observing whether the wavelength or the power of the cladding mode has a large change or whether there is a secondary peak.

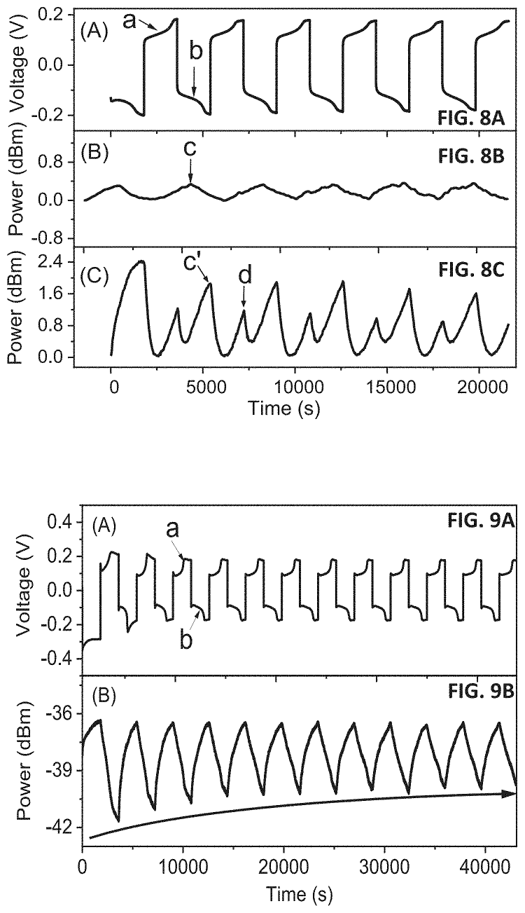

FIGS. 8A-8C show the relationship between the dendrite growth state of the electrode and output light during charging and discharging. As shown in FIG. 8, the abscissa represents the measurement time (from 0 to 20000 s), while the ordinates in the top, middle, and bottom panels represent power the voltage (from −0.25 V to 0.20 V), power (from −0.6 dBm to 1.2 dBm) and power (from 0 dBm to 2.4 dBm). FIG. 8A shows the relationship between the voltage signal and time. Among them, “a” represents the charging process and “b” represents the discharging process. It means that during the period from 0 s to 20000 s, the charging voltage remains the same, and the discharge voltage remains the same, and the frequency of charging and discharging is equal, so as to measure the optical signal of the electrochemical device. FIG. 8B shows a graph of the optical signal change of the electrochemical device without dendrite growth. FIG. 8C shows a graph of the optical signal change of the electrochemical device with dendrite growth. It can be seen from the figures that in the absence of dendrite growth, the wavelength or the power of the cladding mode hardly changes or changes slightly, and there is only one main peak “c”. However, when there is dendrite growth, there are two phenomena of wavelength and cladding mode power, one is the increase in amplitude, and the other is the double peak, namely the main peak “c” and the secondary peak “d”. Therefore, the presence or absence of dendrite growth can be qualitatively judged from the wavelength or the power of the cladding mode. Notably, the electrochemical devices are determined to be unhealthy if dendrite growth.

In another possible implementation manner, the growth of dendrites can be quantitatively analyzed by the change of wavelength or the power of the cladding mode.

FIGS. 9A and 9B show the electrical signal and optical signal during charging and discharging. The abscissa of FIG. 9A indicates the measurement time (from 0 s to 40000 s), and the ordinate represents the voltage (from −04V to 0.4V.) Among them, “a” represents the charging process and “b” represents the discharging process. It means that during the period from 0 s to 40000 s, the charging voltage remains the same, and the discharge voltage remains the same, and the frequency of charging and discharging is equal, so as to measure the optical signal of the electrochemical device. FIG. 9B shows the change of the wavelength or the power of the cladding mode with the growth of dendrites. The abscissa represents the measurement time (from 0 to 40000 s), and the ordinate represents the wavelength or the power of the cladding mode (only the power of the cladding mode is shown in the figure), and the range is from −42 dBm to −36 dBm. From the figure, it can be seen that the wavelength or the power of the cladding mode has a certain quantitative relationship with the growth of dendrites. For example, linear relationships, quadratic function relationship, etc. The embodiments of this application are not limited.

Therefore, the much stronger optical response together with a noticeably distinctive secondary peak detected in Li-dendrite-growth condition. It reveals that the remarkable increase in optical response is result of an low efficient or blocked Li-ion transport in the vicinity of the Li metal electrode (means a reduced Coulombic efficiency of battery) and the noticeably distinctive secondary peak is originated from the dynamic balancing between Li-ion depletion and Li dendrite growth (like a “periodic respiration” effect in dendrite growth and dissolution within each charging/discharging cycle), thereby providing a potentially useful early warning of the dendrite growth and decrease the risk for catastrophic battery failure.

In Example 3, the ion transport can be derived from the power changes of the cladding mode or an SPR for detecting the state of charge (SoC) of the electrochemical devices.

During the charging and discharging process of the electrochemical device, ion transport activity occurs on the electrode-electrolyte surface. The process of ion transport will cause changes in the cladding mode or an SPR, which in turn can infer the SoC of the electrochemical device.

A possible implementation is to calculate the change in the refractive index of the electrolyte based on the cladding mode or an SPR, and determine the SoC according to the change in the refractive index. Its implementation can refer to the related descriptions of FIG. 3A to FIG. 4B.

Another possible implementation is to take a derivative of one of the cladding mode or an SPR with respect to time, so that the SoC of the electrochemical device can be determined. Optionally, the derivative is not limited to the first-order derivative, and it may also be a second-order derivative, a third-order derivative, and the like. This embodiment of the application does not limit this.

Herein, the optical fiber probe is a tilted fiber grating coated with a metal film, and the fiber probe is implanted into an electrode and tightly connected to the electrode surface, where the electrode can be plated with a MnO₂ film. The embodiments of this application are not limited.

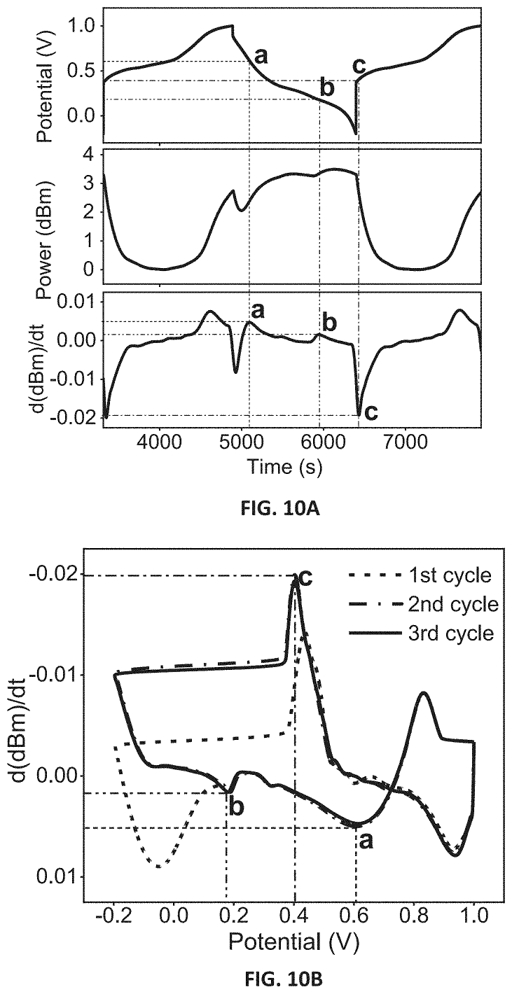

The curves of galvanostatic charge/discharge (GCD) test, SPR power and differential of light power are exhibited in FIG. 10A. The differential of light power (Double-dotted line FIG. 10A) is obtained by taking the derivative of the SPR power level with respect to time, which represents the rate of change of the optical power. It shown that the changes of electrochemical curves are highly consistent with the optical results. And most importantly, it is found that it shows a stable and reproducible correlation with ion transfer rate. At the time corresponding to the two discharging platforms of 0.62 V (point a) and 0.18 V (point b), the SPR power decreases, while the differential of light power curve reaches the peak. This is because ions quickly transfer and intercalate cathode material during discharge, thus reducing the ion concentration at the electrode-electrolyte interface. And optical curves flatten out towards the end of the discharge. While starting charging (point c), the optical signal decreased sharply and a peak was observed in d(dBm)/dt curve. Since both the electrochemical signal and optical signal are functions of time, the change rate of the optical signal can be mapped to the voltage as a P′/V relationship curve. FIG. 10B presents the P′/V curves of the first third charging and discharging cycles of MO cathode, which is similar in shape to the CV curve. The 1st cycle is irreversible due to the change in crystal structure, which is common in MnO₂ electrode materials. The curve gradually levels off after the 2^{nd} cycle, indicating a reversible redox reaction with ion intercalation/deintercalation. Furthermore, it can also observe a charging plateau and two discharging plateaus.

Finally, it should be noted that the foregoing embodiments are merely intended for describing the technical solutions of the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, without departing from the scope of the technical solutions of the embodiments of the present disclosure.

1. A method for monitoring a state of an electrochemical device by means of an optical fiber probe arranged inside the electrochemical device, the method comprising the steps of:
(1) shedding an input light into the optical fiber probe and detecting an output light transmitted from the optical fiber probe; and
(2) determining a state of health (SoH) of the electrochemical device based on the output light.

2. The method of claim 1, wherein step (2) of determining a state of health (SoH) of the electrochemical device based on the output light comprises the sub-steps of:
(i) obtaining a refractive index based on the output light; and
(ii) determining the SoH of the electrochemical device based on a change of the refractive index relative to a prior state of the electrochemical device.

3. The method of claim 2, wherein sub-step (i) of obtaining a refractive index based on the output light comprises the sub-steps of:
(a) obtaining one of a cladding mode or a surface plasmon resonance (SPR) from the output light; and
(b) calculating the refractive index based on the one of the cladding mode or the SPR.

4. The method of claim 3, wherein in sub-step (a) of obtaining one of a cladding mode or a surface plasmon resonance (SPR) from the output light, a core mode is further obtained from the output light, wherein in sub-step (b), the refractive index is calculated further with correction of the core mode.

5. The method of any one of claims 2-4, wherein sub-step (ii) of determining the SoH of the electrochemical device based on a change of the refractive index relative to a prior state of the electrochemical device further comprises:
determining that the electrochemical device is unhealthy if the refractive index is changed by at least 1% relative to the prior state of the electrochemical device.

6. The method of claim 1, wherein step (2) of determining a state of health (SoH) of the electrochemical device based on the output light comprises the sub-steps of:
(i) obtaining one of a cladding mode or a surface plasmon resonance (SPR) from the output light; and
(ii) determining the SoH of the electrochemical device based on a wavelength shift or an amplitude change of the one of the cladding mode or the SPR relative to a prior state of the electrochemical device.

7. The method of claim 6, wherein sub-step (ii) of determining the SoH of the electrochemical device based on a wavelength shift or an amplitude change of the one of the cladding mode or the SPR relative to a prior state of the electrochemical device comprises the sub-steps of:
taking a derivative of the one of the cladding mode or the SPR with respect to one selected from a group consisting of time, voltage, current, resistance and capacity; and
determining the SoH of the electrochemical device based on the derivative.

8. The method of claim 6, wherein, wherein sub-step (ii) of determining the SoH of the electrochemical device based on a wavelength shift or an amplitude change of the one of the cladding mode or the SPR relative to a prior state of the electrochemical device comprises:
(a) determining that the electrochemical device is unhealthy if an amplitude or wavelength of the one of the cladding mode or the SPR is changed by at least 1% relative to the prior state of the electrochemical device.

9. The method of claim 8, wherein at least one portion of a detection surface of the optical fiber probe is in contact with an electrolyte of the electrochemical device, wherein the determining that the electrochemical device is unhealthy in sub-step (a) comprises:
determining that the electrolyte is unhealthy.

10. The method of claim 1, wherein step (2) of determining a state of health (SoH) of the electrochemical device based on the output light comprises the sub-steps of:
(i) obtaining one of a cladding mode or a surface plasmon resonance (SPR) from the output light; and
(ii) determining the electrochemical device is unhealthy if at least one secondary peak is present in the one of the cladding mode or the SPR.

11. The method of claim 10, wherein the optical fiber probe is inside or in a proximity of an electrode of the electrochemical device, wherein the determining that the electrochemical device is unhealthy in sub-step (ii) comprises:
determining that the electrode is unhealthy.

12. The method of any one of preceding claims, further comprising, after step (1) of shedding an input light into the optical fiber probe and detecting an output light transmitted from the optical fiber probe:
determining a state of charge (SoC) of the electrochemical device based on the output light.

13. The method of claim 12, wherein the determining a state of charge (SoC) of the electrochemical device based on the output light comprises the sub-steps of:
(i) obtaining one of a cladding mode or an SPR from the output light; and
(ii) determining the SoC of the electrochemical device based on the one of the cladding mode or the SPR.

14. The method of claim 13, wherein sub-step (ii) of determining the SoC of the electrochemical device based on the one of the cladding mode or the SPR comprises:
calculating a refractive index based on the one of the cladding mode or the SPR; and
determining the SoC based the refractive index.

15. The method of claim 13, wherein sub-step (ii) of determining the SoC of the electrochemical device based on the one of the cladding mode or the SPR comprises:
taking a derivative of the one of the cladding mode or the SPR with respect to one selected from a group consisting of time, voltage, current, resistance and capacity; and
determining the SoC based the derivative.

16. The method of any one of claims 13-15, wherein in sub-step (i) of obtaining one of a cladding mode or an SPR from the output light, a core mode is further obtained from the output light, wherein in sub-step (ii) of determining the SoC of the electrochemical device based on the one of the cladding mode or the SPR, the SoC is determined with further correction of the core mode.

17. The method of any one of preceding claims, further comprising, after step (1) of shedding an input light into the optical fiber probe and detecting an output light transmitted from the optical fiber probe:
determining at least one of a temperature, a pressure, a strain, a displacement, a vibration, or a gas inside the electrochemical device based on the output light.

18. The method of claim 17, wherein a gas is determined in the sub-step of determining at least one of a temperature, a pressure, a strain, a displacement, a vibration, or a gas inside the electrochemical device based on the output light, wherein the gas comprises at least one of O₂, H₂, CO, CO₂, C₂H₄, CH₄, or HF.

19. A system for monitoring a state of an electrochemical device, comprising:
an optical fiber probe arranged inside the electrochemical device;
a light source apparatus, optically coupled to a first end of, and configured to provide an input light into, the optical fiber probe;
a signal detection and processing apparatus optically coupled to the optical fiber probe, wherein the signal detection and processing apparatus is configured:
to receive an output light from the optical fiber probe;
to obtains signals from the output light; and
to process the signals such that step (2) in any one of the method according to claims 1-17 is implemented.

20. The system of claim 19, wherein the optical fiber probe is one selected from a group consisting of an optical fiber with a grating, an optical fiber with a cavity, a microfiber, a nanofiber, a tapered fiber, a side-polished fiber, a microstructure fiber and a photonic crystal fiber.

21. The system of claim 20, wherein the optical fiber probe is an optical fiber with a grating, wherein a type of the grating is one selected from a group consisting of fiber Bragg grating (FBG), tilted fiber Bragg grating (TFBG), long period fiber grating (LPG), chirped fiber gratings, and phase shift gratings.

22. The system of claim 21, wherein the type of the gratings is tilted fiber Bragg grating (TFBG).

23. The system of claim 22, wherein the optical fiber probe comprises a core and a cladding surrounding the core, wherein the core is provided with a tilted grating having an inclination angle less than 90° relative to a longitudinal axis of the core.

24. The system of claim 23, wherein the inclination angle of the tilted grating is in a range of approximately 2°-45°.

25. The system of claim 23 or claim 24, wherein the optical fiber probe further comprises an SPR layer coating an outer surface of the cladding, wherein the SPR layer has a composition active to surface plasmon resonance (SPR), wherein the composition comprises at least one of gold (Au), silver (Ag), platinum (Pt), copper (Cu) or aluminum (Al), a semiconductor material, a metal oxide material, a two-dimensional (2D) material, or an optical metamaterial.

26. The system of claim 25, wherein the optical fiber probe further comprises a protective film layer over an outer surface of the SPR layer, wherein the protective film layer comprises at least one of diamond, silicon, indium tin oxide (ITO), zinc peroxide (ZnO2), tin oxide (SnO2), indium oxide (In□O□), polyethylene (PE) or polypropylene (PP).

27. The system of claim 25 or claim 26, wherein the optical fiber probe further comprises a transition film layer sandwiched between the cladding and the SPR layer, configured to improve adhesion of the base film layer to the optical fiber, wherein the transition film layer comprises at least one of titanium (Ti), molybdenum (Mo), or chromium (Cr).

28. The system of any one of claims 19-27, wherein the optical fiber probe comprises a mirror arranged at a second end thereof, wherein the mirror has a reflective surface facing inside the optical fiber probe.

29. The system of any one of claims 19-28, wherein the optical fiber probe has a single-point configuration.

30. The system of any one of claims 19-28, wherein the optical fiber probe has a multi-point configuration having a plurality of points arranged in series or in parallel.

31. The system of any one of claims 19-30, wherein the optical fiber probe is arranged such that at least one portion thereof is in contact with an electrolyte of the electrochemical device.

32. The system of any one of claims 19-30, wherein the optical fiber probe is arranged such that at least one portion thereof is in proximity of an electrode of the electrochemical device.

33. The system of any one of claims 19-32, wherein the electrochemical device is a battery or a supercapacitor.

34. The system of claim 33, wherein the electrochemical device is a battery, selected from a group consisting of a lithium-ion battery, a lead-acid battery, a lithium iron phosphate battery, a fuel battery, a sodium-ion battery, a sodium-sulfur battery, a flow battery, a solid state battery, a hybrid solid-liquid state battery, a lithium metal battery, or a Zₙ—MnO₂ battery.
